(19) United States
(12) Patent Application Publication
(10) Pub. No.: US 2014/0116327 A1
(43) Pub. Date: May 1, 2014

(54) METHOD AND APPARATUS FOR FABRICATING FREE-STANDING GROUP III NITRIDE CRYSTALS

(71) Applicant: Maxim Blashenkov, St. Petersburg (RU)

(72) Inventor: Maxim Blashenkov, St. Petersburg (RU)

(73) Assignee: "PERFECT CRYSTALS" LIMITED LIABILITY COMPANY, St. Petersburg (RU)

(21) Appl. No.: 14/122,835

(22) PCT Filed: May 31, 2012
(86) PCT No.: PCT/EP2012/060225

§ 371 Date: Nov. 27, 2013

Related U.S. Application Data
(60) Provisional application No. 61/491,393, filed on May 31, 2011.

(51) Int. Cl. C30B 25/20; C30B 25/18; C30B 25/08

(52) U.S. Cl. CPC C30B 25/20; C30B 25/08; C30B 25/186
USPC 117/92; 117/204

(57) ABSTRACT

The method for fabricating a free-standing group III nitride plate (6) comprises the steps of growing at a growth temperature within a growth reactor (7) a first group III nitride layer (2) on a foreign growth substrate (1); growing at the growth temperature within the growth reactor (7) a second group III nitride layer (5) on the first group III nitride layer (2); and separating by laser lift-off the second group III nitride layer (5) from the growth substrate (1) so as to form a free-standing group III nitride plate (6). According to the present invention, the step of separating the second group III nitride layer (5) from the growth substrate (6) is performed at the growth temperature and within the growth reactor (7), and the method further comprises a step of treating the first group III nitride layer (1) by laser treatment at the growth temperature within the growth reactor (7) so as to provide stress relaxation areas (4) in the first group III nitride layer (2).

### FIELD OF THE INVENTION

The present invention relates, in general, to methods and apparatuses for fabricating free-standing group III nitride crystals. The present invention is focused on a method for fabricating a free-standing group III nitride crystal, the method comprising depositing a high-quality quasi-bulk group III nitride single crystal layer on a foreign growth substrate and separating the so formed nitride crystal from the foreign substrate. The present invention is also focused on an apparatus for such method for fabrication.

### BACKGROUND OF THE INVENTION

Due to the many advantageous properties thereof, nitrides of group III metals, i.e. the so called III-nitrides which can also be denoted by the general formula “A3N”, form an important group of semiconductor materials for electronic and optoelectronic applications. As one example, Gallium Nitride (GaN) in its many variations has become one of the most important semiconductor materials for optoelectronic devices such as high brightness Light Emitting Diodes (LEDs) for lighting applications.

Nitride-based devices are typically grown epitaxially as layered structures on substrates. In the case of heteroepitaxy, i.e. when the substrate is of different material than the epitaxially grown crystal, the differences in thermal expansion coefficients and lattice constants between the hetero-substrate and grown A3N plate lead to stress generation at the layer interface area, particularly during the change of the growth temperature or cooling down of the grown structure from the growth temperature. These stresses result in high density of different defects like pits and sometimes even cracks.

Thus, as well-known in the art, in order to avoid such undesired effects due to the different lattice constants and thermal expansion coefficients between the substrate and the device layers grown on it, a growth substrate should most preferably be formed of the same material as the device layers. However, unavailability of high quality, preferably stand-alone III-nitride templates is a well-known problem in this field, having compelled the device manufacturers to use foreign substrates. As an example, common examples of foreign substrate materials for GaN-based devices are sapphire and silicon carbide.

Several techniques for fabricating free-standing group III nitride substrates have been proposed. Those techniques typically include combination of growth steps, mask deposition, and finally removal of the initial growth substrate. Standard horizontal or vertical CVD reactors are commonly used. Generally, such substrates can be produced by depositing a thick layer of a group III nitride, typically having a thickness of several hundreds of micrometers, on a foreign substrate such as sapphire, Al2O3, SiC, Si, etc., and subsequently separating the foreign substrate from the deposited nitride layer(s). Substrate removal can be accomplished in various manners including mechanical grinding, laser lift-off, etching, etc. However, this conventional approach has several limitations. III-nitride deposition process necessitates high temperatures (typically 1000° C. to 1100° C.). During cooling down from the growth temperature to room temperature, the III-nitride film undergoes a biaxial stress caused by the large difference between the thermal-expansion coefficients of the nitride crystal and the substrate material. This stress can cause cracking, bowing, generation of crystal defects, and other adverse effects.

US 2006/0148186 A1 discloses a process wherein, in order to avoid those negative effects, a laser beam is directed to the interface of the nitride and the foreign substrate in order to separate them in the growth chamber before cooling down the sample. However, this approach cannot remove the basic problem of the stress-induced defects in the nitride layer during the nitride deposition.

In addition to direct deposition of a thick nitride layer on a foreign substrate, also well-known are several techniques wherein an intermediate or buffer nitride layer is first formed on a foreign substrate. A thick nitride crystal layer is then grown on the porous intermediate layer. Finally, the thick nitride layer is separated from the substrate along the intermediate intermediate layer. As an example, US 2002/0182889 A1 discloses a method for producing free-standing substrates, wherein after deposition of an intermediate thin nitride layer, a laser beam is used to cause a loss of coherence between a first, intermediate nitride layer and the growth substrate. After that, a thick nitride layer is grown on the intermediate nitride layer. Said loss of coherence then facilitates separation of the grown nitride from the growth substrate at the end of the process.

Due to said problems of the prior art approaches, despite the existence of some approaches proposed to solve those problems, there is still a continuous and intense need in the market for effective and well-controlled methods and apparatuses for fabricating stand-alone, i.e. free-standing high quality group III nitride crystals.

### PURPOSE OF THE INVENTION

The purpose of the present invention is to provide solutions for the above need.

### SUMMARY OF THE INVENTION

The present invention is focused on a method for fabricating a free-standing group III nitride plate, i.e. a crystal in the form of a wafer, having low stresses and low defect density. The group III nitride can be e.g. gallium nitride GaN.

The method comprises the steps of: growing at a growth temperature within a growth reactor a first group III nitride layer on a foreign growth substrate; growing at the growth temperature within the growth reactor a second group III nitride layer on the first group III nitride layer; and separating by laser lift-off the second group III nitride layer from the growth substrate so as to form a free-standing group III nitride plate.

Said steps of growing can be performed using any known Chemical Vapor Deposition (CVD) process, including but not limited to metal-organic CVD and Hydrid Vapor Epitaxy HVPE.

The foreign substrate can be of any material suitable for CVD deposition of group III nitrides, and different from the nitride to be grown. One widely used materials is sapphire.

The initial, i.e. the first group III nitride layer is a buffer layer between the foreign growth substrate preferably thin with a thickness below 10 μm. In any case, the thickness should be so low that no stress-induced defects occur in this layer. The thickness thereof can be even as low as e.g. 300 nm. In general, in growing the first group III nitride layer, processes and principles as such known in the art can be used.

The second group III nitride layer is the layer forming the actual free-standing plate. Thus, its thickness must provide sufficient mechanical strength. For example, for a wafer having a size of 2 inches, the suitable thickness can be e.g. about 500 μm. If higher thickness is grown, it may be possible to slice the fabricated plate into two or more thinner wafers.

According to the present invention, the step of separating by laser lift-off the second group III nitride layer from the growth substrate by means of laser lift-off is performed at the growth temperature and within the growth reactor.

Said principle of performing the laser lift-off at the growth temperature in the growth reactor provides great advantages. When the lift-off is performed and the second group III nitride thus separated from the growth substrate in a high temperature and without first removing the grown sample from the growth reactor, the harmful stress generation due to the different thermal behavior of the substrate and the grown nitride during the decrease of temperature is avoided. Then, crack-free, low-defect density nitride plate can be produced. Moreover, the entire process can be performed efficiently in situ.

By growth temperature is meant here the temperature range used in the steps of growing the first and the second group III nitride layers. Typically this lies around about 1000° C. The temperature in which the laser lift-off is performed is not required to be exactly within the lower and upper limits of the growth temperature range but may slightly deviate from said range in so far as the temperature is sufficiently low to avoid said harmful stress generation. Preferably, the step of separating by laser lift-off the second group III nitride layer from the growth substrate is performed at a temperature which is within ±50° C. from the growth temperature, i.e. is below or exceeds the growth temperature range by no more than 50° C.

According to the present invention, the method further comprises a step of treating the first group III nitride layer by laser treatment at the growth temperature within the growth reactor, before growing the second group III nitride layer, so as to provide stress relaxation areas in the first group III nitride layer.

In this step, a first group III nitride layer, i.e. the buffer layer, with relaxed inherent stresses is produced. As a result of this, the stress level of the second group III nitride layer grown on this first layer and finally forming the free-standing group III nitride plate is further lowered. The initial, i.e. the first group III nitride layer grown on the foreign growth substrate necessarily have some stresses. By suitable treatment of a strained nitride layer by laser it is possible to provide areas in this layer where the initial stress level is reduced. In the present invention, this results in reduced stress generation also in the second group III nitride layer grown on this first layer.

Preferably, the step of treating the first group III nitride layer by laser treatment comprises at least one of cutting, drilling, and etching. Preferably, trenches, holes, or other cavities are formed in the first group III nitride layer during this treatment. The stress relaxation areas, i.e. areas of reduced stresses are formed between such cavities from which the nitride material is removed. The cavities are preferably deep extending even up to the interface between the nitride and the growth substrate. They can be e.g. in the form of grooves. The depth of such grooves should be substantially equal to the width of the grooves.

In the method of the present invention, in the step of growing at a growth temperature within a growth reactor a first group III nitride layer on a foreign growth substrate comprises, a first group III nitride layer having a plurality of sub-layers may be formed. A multi-layered inner structure of the first nitride layer can help to achieve a smooth and low-defect density surface of this layer acting as the growth surface for the second group III nitride layer.

According to a second aspect, the present invention is focused on a growth reactor for growing group III nitride layers on a foreign growth substrate. The growth reactor of the present invention comprises a first zone for said growing of group III nitride layers by CVD deposition.

According to the present invention, the growth reactor further comprises a second zone and a laser lift-off system for separating, in the second zone, by laser lift-off, from the back side of the grown nitride, a group III nitride layer from the growth substrate.

Thus, in the reactor design of the present invention, in addition to a standard growth zone(s), a special additional zone for laser treatment is added. This second zone and the laser lift-off system of the growth reactor enable separation of the second group III nitride from the growth substrate at the growth temperature within the growth reactor, so without first removing the grown layer stack from the reactor. This leads to the great advantages as described above in the context of the method aspect of the present invention.

By backside is meant here the side of the substrate. Thus, the laser beam used in the lift-off is directed to the grown layer stack via the free back surface of the growth substrate. Respectively, the front side refers to the opposite side, i.e. the side of the free surface of the grown first or second group III nitride layer.

Further, according to the present invention, the growth reactor also comprises a laser treatment system for treating, in the second zone, from the front side of the grown nitride, a group III nitride layer grown in the first zone so as to provide stress relaxation areas in the group III nitride layer. The laser treatment system is preferably arranged to treat the group III nitride layer by at least one of laser cutting, drilling, and etching.

The advantages achievable by means of the second zone having, in addition to the laser lift-off system, also the laser treatment system, are described above in the context of the method aspect of the present invention.

To summarize, the method and the reactor according to the present invention has the following features:

i) The method comprises the following steps: (1) growth of a thin first/initial/buffer layer on top of the hetero-substrate; (2) laser treatment of said first/initial/buffer layer; (3) growth of a second, relatively thick layer on top of said first/initial/buffer layer; (4) lift-off of a plate from a hetero-substrate.

ii) All process steps are performed within the same growth reactor.

iii) The process does not require any lithography.

iv) The reactor has two main operation zones. The first is the standard growth zone for CVD deposition and the second is the novel treatment zone for laser treatments.

v) The processes in the treatment zones is performed substantially at the same temperature as the growth of the nitride layers.

vi) The second zone may be used both for front side treatment and for backside actions such as the lift-off.

vii) Laser(s) may be used for stress relaxation of the first group III nitride layer by front side cutting, drilling or etching.

viii) Backside actions can include but are not limited to laser lift-off procedure of the grown plate from the substrate.

### BRIEF DESCRIPTION OF THE DRAWINGS

FIG. 1 schematically depicts a method for fabricating high-quality A3N single crystal plates according to the present invention.

FIG. 2 schematically depicts a schematic of a growth reactor according to the present invention.

### DETAILED DESCRIPTION OF THE INVENTION

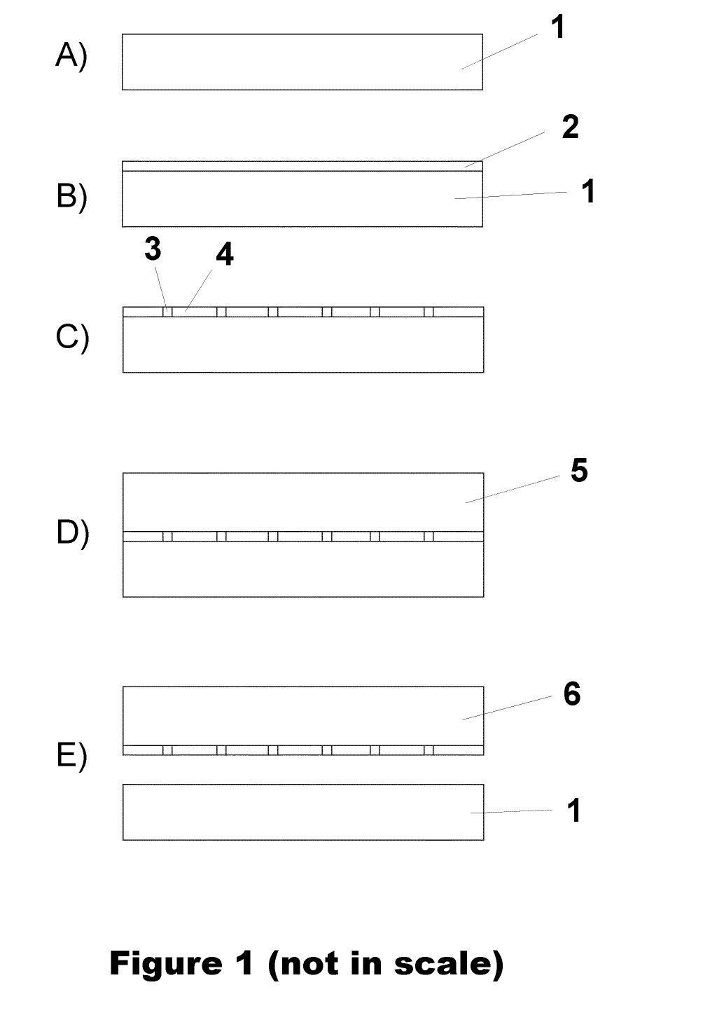

In the process illustrated in FIG. 1, the growth substrate 1 is a hetero-substrate, i.e. it is made from any material suitable for group III nitride growth but not from the same material as the nitride itself.

First, in step b), an initial A3N layer 2 is deposited by means of CVD. This layer is thin (<10 μm) to avoid defect formation. This layer can also comprise a plurality of layers aimed to provide smooth and defect-free initial A3N surface. Next, the grown layer stack is moved to the treatment zone of the growth reactor.

The temperature in the treatment zone is kept substantially at the same level as in the growth zone. Then, in step c), a laser treatment, such as cutting, drilling, etching, etc. is performed from front side of the structure. During this laser treatment trenches, holes, or other cavities 3 are created in the initial A3N layer, which provide areas 4 of relaxed stresses between the cavities. After the treatment, the grown stack is moved back to the growth zone of the reactor.

Then, in step d), growth of a thick group III nitride layer 5 (up to few hundreds μm) is performed on top of the initial nitride layer 2 to form a thick-enough A3N layer capable to keep flat surface after removal of the hetero-substrate. Also this thick A3N layer can comprise a plurality of sub-layers.

Next, the grown stack is again moved to the treatment zone of the growth reactor. The temperature in the treatment zone is again kept substantially at the same level as in the growth zone. The hetero-substrate 1 is separated from the thick nitride layer by laser lift-off so as to form a free-standing group III nitride plate 6. Finally, the plate is cooled down to room temperature.

Due to the separation of the growth substrate 1 from the grown nitride before cooling down the grown nitride plate, no thermal stresses are generated in the plate during said cooling down, and thus no cracks or other stress-induced defects are formed in the completed nitride plate 6.

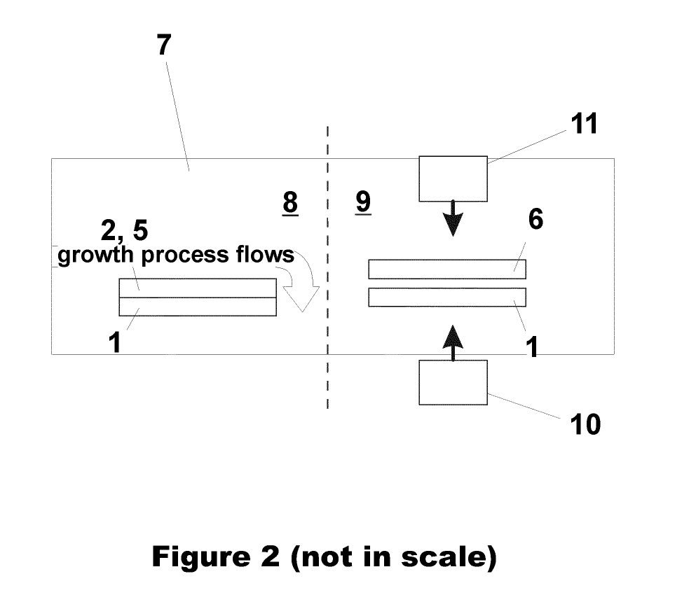

FIG. 2 discloses a schematic view of the novel reactor design. The reactor 7 has two main operation zones. The first is a standard growth zone 8 for CVD deposition. There can also be a plurality of growth zones in the reactor. The second zone 9 is a treatment zone for laser treatments. In operation, the treatment zone 9 can be kept at the same temperature as the growth zone 8. The treatment zone 9 has a laser treatment system 10 and a laser lift-off system 11 for performing laser treatment on the grown nitride layers 2, 5 and separating the grown nitride layers from the growth substrate 1, respectively. The laser treatment system 10 can be used for front side treatment on the grown nitride layers 2, 5. This treatment can include e.g. cutting, drilling, or etching the nitride. The laser lift-off is primarily used for separating the growth substrate from the grown nitride 6 by lift-off from the backside of the grown stack. However, the use of the laser lift off is not limited to this purpose only but it may be used for other backside actions also. For example, a backside laser beam may be used to create voids at the interface between the substrate and the III-nitride layer or for scribing the foreign substrate.

It is clear that the invention is not limited to the above examples only. Instead, the embodiments of the present invention may freely vary within the scope of the claims.

1. A method for fabricating a free-standing group III nitride plate, the method comprising the steps of:
growing at a growth temperature within a growth reactor a first group III nitride layer on a foreign growth substrate;
growing at the growth temperature within the growth reactor (7) a second group III nitride layer on the first group III nitride layer; and
separating by laser lift-off the second group III nitride layer from the growth substrate so as to form a free-standing group III nitride plate;
characterized in that
the step of separating by laser lift-off the second group III nitride layer from the growth substrate by means of laser lift-off is performed at the growth temperature and within the growth reactor, and that
the method further comprises a step of treating the first group III nitride layer by laser treatment at the growth temperature within the growth reactor, before growing the second group III nitride layer, so as to provide stress relaxation areas in the first group III nitride layer.

2. A method as defined in claim 1, wherein in the step of separating by laser lift-off the second group III nitride layer from the growth substrate is performed at a temperature which is within ±50° C. from the growth temperature.

3. A method as defined in claim 1 wherein the step of treating the first group III nitride layer by laser treatment comprises at least one of cutting, drilling, and etching.

4. A method as defined in claim 3, wherein the step of treating the first group III nitride layer by laser treatment comprises formation of trenches, holes, or other cavities in the first group III nitride layer.

5. A method as defined in any of claim 1, wherein, in the step of growing at a growth temperature within a growth reactor a first group III nitride layer on a foreign growth substrate, a first group III nitride layer having a plurality of sub-layers is formed.

6. A growth reactor for growing group III nitride layers on a foreign grown substrate, the growth reactor comprising a first zone for said growing of group III nitride layers by CVD deposition, characterized in that the growth reactor further comprises
a second zone and a laser lift-off system for separating, in the second zone, by laser lift-off, from the back side, a group III nitride layer from the growth substrate; and
a laser treatment system for treating, in the second zone, from the front side, a group III nitride layer grown in the first zone so as to provide stress relaxation areas in the group III nitride layer.

7. A growth reactor as defined in claim 6, wherein the laser treatment system is arranged to treat the group III nitride layer by at least one of laser cutting, drilling, and etching.

8. A method as defined in claim 2 wherein the step of treating the first group III nitride layer by laser treatment comprises at least one of cutting, drilling, and etching.

9. A method as defined in any of claim 2, wherein, in the step of growing at a growth temperature within a growth reactor a first group III nitride layer on a foreign growth substrate, a first group III nitride layer having a plurality of sub-layers is formed.

10. A method as defined in any of claim 3, wherein, in the step of growing at a growth temperature within a growth reactor a first group III nitride layer on a foreign growth substrate, a first group III nitride layer having a plurality of sub-layers is formed.

11. A method as defined in any of claim 4, wherein, in the step of growing at a growth temperature within a growth reactor a first group III nitride layer on a foreign growth substrate, a first group III nitride layer having a plurality of sub-layers is formed.
